(19) United States
(12) Patent Application Publication
(10) Pub. No.: US 2024/0244896 A1
(43) Pub. Date: Jul. 18, 2024

(54) DISPLAY PANEL AND ELECTRONIC DEVICE INCLUDING THE SAME

(71) Applicant: Samsung Display Co., LTD., Yongin-si (KR)

(72) Inventors: Jongchan LEE, Yongin-si (KR); Seunggyu TAE, Yongin-si (KR); Yuri OH, Yongin-si (KR); Kibok YOO, Yongin-si (KR); Donghyeok LEE, Yongin-si (KR); Jinsuk LEE, Yongin-si (KR)

(21) Appl. No.: 18/373,377

(22) Filed: Sep. 27, 2023

(30) Foreign Application Priority Data
Jan. 12, 2023 (KR) 10-2023-0004976

(51) Int. Cl. H10K 59/124; G09G 3/3233

(52) U.S. Cl. CPC H10K 59/124; G09G 3/3233; G09G 2300/0819; G09G 2300/0852; G09G 2300/0861

(57) ABSTRACT

A display panel includes a substrate including an opening area, a display area surrounding at least a portion of the opening area, and an intermediate area between the opening area and the display area, a light-emitting diode disposed on the display area and including a pixel electrode, an opposite electrode, and an intermediate layer between the pixel electrode and the opposite electrode, an inorganic insulating layer disposed on the intermediate area and defining a trench surrounding the opening area, and a separator disposed on an upper surface of the inorganic insulating layer and a side surface of the inorganic insulating layer, the side surface defining the trench, in the intermediate area, where the separator includes a protrusion at a corner portion of the inorganic insulating layer where the upper surface meets the side surface.

This application claims priority to Korean Patent Application No. 10-2023-0004976, filed on Jan. 12, 2023, and all the benefits accruing therefrom under 35 U.S.C. § 119, the content of which in its entirety is herein incorporated by reference.

### BACKGROUND

### 1. Field

One or more embodiments relate to a display panel and an electronic device including the display panel.

### 2. Description of the Related Art

Recently, applications of display panels have diversified. In addition, as display panels become thinner and lighter in weight, the display panels are more widely used in various types of electronic device.

While an area of display panels, which is occupied by a display area, is expanded, various functions linked to or associated with display panels are being added. As a method of adding various functions in display panels having an expanded display area, research is being conducted to arrange various components in a portion of the display area.

### SUMMARY

One or more embodiments include a display panel having an area in which various types of components are arranged in a display area with improved reliability, and an electronic device including the display panel.

According to one or more embodiments, a display panel includes a substrate including an opening area, a display area surrounding at least a portion of the opening area, and an intermediate area between the opening area and the display area, a light-emitting diode disposed on the display area and including a pixel electrode, an opposite electrode, and an intermediate layer between the pixel electrode and the opposite electrode, an inorganic insulating layer disposed on the intermediate area and defining a trench surrounding the opening area, and a separator disposed on an upper surface of the inorganic insulating layer and a side surface of the inorganic insulating layer, the side surface defining the trench, in the intermediate area, where the separator includes a protrusion at a corner portion where the upper surface meets the side surface.

In an embodiment, the protrusion may protrude toward the inside of the trench.

In an embodiment, an inclined surface of the separator, located inside the trench, may be reversely tapered by the protrusion.

In an embodiment, the side surface of the inorganic insulating layer, defining the trench, may be forward tapered.

In an embodiment, the separator may include a plurality of metal layers.

In an embodiment, a width of the trench may be less than or equal to 3.5 μm.

In an embodiment, a depth of the trench may be greater than or equal to 0.5 μm.

In an embodiment, the intermediate layer may include an emission layer disposed to correspond to the pixel electrode and a functional layer extending from the display area to the intermediate area, and the functional layer may be disposed on the separator.

In an embodiment, the functional layer may include a first portion disposed outside the trench and a second portion disposed inside the trench and separated from the first portion.

In an embodiment, the opposite electrode may include a first portion disposed outside the trench and a second portion disposed inside the trench and separated from the first portion.

According to one or more embodiments, an electronic device includes a display panel comprising an opening area, a display area surrounding at least a portion of the opening area, and an intermediate area between the opening area and the display area, and a component disposed to overlap the opening area of the display panel, where the display panel includes a substrate, a light-emitting diode disposed on the substrate to overlap the display area and including a pixel electrode, an opposite electrode, and an intermediate layer between the pixel electrode and the opposite electrode, an inorganic insulating layer disposed on the substrate to overlap the intermediate area and defining a trench surrounding the opening area, and a separator disposed on the substrate to overlap the intermediate area and defining a groove overlapping the trench, where a width of the groove increases as being toward the substrate.

In an embodiment, an inclined surface of the separator, defining the groove, may be reversely tapered.

In an embodiment, the separator may include a first metal layer defining a first groove and a second metal layer stacked on the first metal layer and defining a second groove, and the first groove and the second groove may overlap each other.

In an embodiment, each of a first thickness of the first metal layer in the first groove and a second thickness of the second metal layer in the second groove may decrease as being toward the substrate.

In an embodiment, each of the first thickness and the second thickness may be in a range of about 0.01 micrometer (μm) to about 0.45 μm.

In an embodiment, a width of the trench may be less than or equal to 3.5 μm.

In an embodiment, a depth of the trench may be greater than or equal to 0.5 μm.

In an embodiment, the intermediate layer may include an emission layer disposed to correspond to the pixel electrode and a functional layer extending from the display area to the intermediate area, and the functional layer may be disposed on the separator.

In an embodiment, the functional layer may include a first portion disposed outside the groove and a second portion disposed inside the groove and separated from the first portion.

In an embodiment, the opposite electrode may include a first portion disposed outside the groove and a second portion disposed inside the groove and separated from the first portion.

### BRIEF DESCRIPTION OF THE DRAWINGS

The above and other features of certain embodiments of the disclosure will be more apparent from the following description taken in conjunction with the accompanying drawings, in which:

FIG. 1 is a schematic perspective view of an electronic device according to an embodiment;

FIG. 2 is a schematic cross-sectional view of an electronic device according to an embodiment, taken along line I-I′ of FIG. 1;

FIG. 3 is a schematic plan view of a display panel according to an embodiment;

FIGS. 4A and 4B are schematic equivalent circuit diagrams of one pixel included in a display panel, according to embodiments;

FIG. 5 is a plan view of an excerpt of a portion of a display panel of the disclosure;

FIG. 6 is a cross-sectional view of a portion of a display panel according to an embodiment, taken along line III-III′ of FIG. 5;

FIG. 7 is a cross-sectional view of an area V of FIG. 6; and

FIGS. 8A and 8B are graphs of the width and depth of a trench formed in an inorganic insulating layer.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” or “at least one selected from a, b and c” indicates only a, only b, only c, both a and b, both a and c, both b and c, all of a, b, and c, or variations thereof.

Various modifications may be applied to embodiments described herein, and particular embodiments will be illustrated in the drawings and described in the detailed description section. The effect and features of the present embodiments, and a method to achieve the same, will be clearer referring to the detailed descriptions below with the drawings. However, the disclosure may be implemented in various forms, not by being limited to the embodiments presented below.

Hereinafter, embodiments will be described in detail with reference to the accompanying drawings, and in the description with reference to the drawings, the same or corresponding components are indicated by the same reference numerals and any repetitive detailed descriptions thereof may be omitted or simplified.

In the present specification, it will be understood that although the terms “first,” “second,” etc. may be used herein to describe various components, these components should not be limited by these terms. These terms are only used to distinguish one component from another.

In the present specification, the expression of singularity includes the expression of plurality unless clearly specified otherwise in context.

In the present specification, it will be further understood that the terms “comprises” and/or “comprising” or “includes” and/or “including” used herein specify the presence of stated features or components, but do not preclude the presence or addition of one or more other features or components.

In the present specification, it will be understood that when a layer, region, or component is referred to as being “on” another layer, region, or component, it can be directly or indirectly on the other layer, region, or component. That is, for example, intervening layers, regions, or components may be present therebetween. In contrast, when an element is referred to as being “directly on” another element, there are no intervening elements present.

In the present specification, it will be understood that when a layer, region, or component is referred to as being “connected to” another layer, area, or component, it can be directly or indirectly connected to the other layer, region, or component. That is, for example, intervening layers, regions, or components may be present. For example, in the present specification, when a layer, region, or component is electrically connected to another layer, region, or component, the layers, regions, or components may not only be directly electrically connected, but may also be indirectly electrically connected via another layer, region, or component therebetween.

In the present specification, the expression “A and/or B” represents A, B, or A and B. In addition, the expression “at least one of A and B” or “at least one selected from A and B” represents A, B, or A and B.

In the present specification, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

In the present specification, when a certain embodiment may be implemented differently, a specific process order may be performed differently from the described order. For example, two consecutively described processes may be performed substantially at the same time or performed in an order opposite to the described order.

Sizes of components in the drawings may be exaggerated or reduced for convenience of explanation. In other words, since sizes and thicknesses of components in the drawings are arbitrarily illustrated for convenience of explanation, the following embodiments are not limited thereto.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

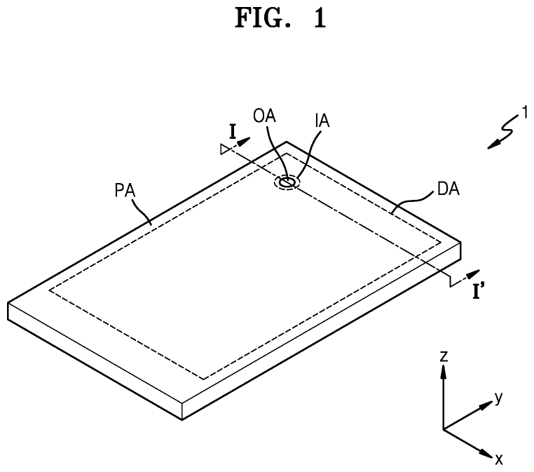

FIG. 1 is a schematic perspective view of an electronic device 1 according to an embodiment.

Referring to FIG. 1, an embodiment of the electronic device 1 displays moving images or still images, and may be used as display screens of various products such as televisions, laptops, monitors, billboards, or Internet of Things (IOTs) as well as portable electronic devices such as mobile phones, smart phones, tablet personal computers (PCs), mobile communication terminals, electronic notebooks, e-books, portable multimedia players (PMPs), navigation devices, or ultra-mobile PCs (UMPCs). In addition, the electronic device 1 according to an embodiment may be used in wearable devices, such as smart watches, watch phones, glass-type displays, and head mounted displays (HMDs). Furthermore, the electronic device 1 according to an embodiment may be used as a display for an instrument panel for vehicles, a center information display (CID) arranged on the center fascia or dashboard of vehicles, a room mirror display in lieu of a side-view mirror of vehicles, or a display arranged at the rear side of a front seat as an entertainment for a rear seat of vehicles. In such an embodiment, the electronic device 1 may be bendable, foldable, or rollable. For convenience of illustration and description, FIG. 1 shows an embodiment where the electronic device 1 is a smartphone.

The electronic device 1 may have a rectangular shape on a plane. For example, as shown in FIG. 1, the electronic device 1 may have a rectangular planar shape having a short side in an x direction and a long side in a y direction. A corner where the short side in the x direction meets the long side in the y direction may be formed round to have a certain curvature or formed at a right angle. A planar shape of the electronic device 1 is not limited to a rectangle, and may be formed into other polygonal, elliptical, or atypical shapes.

The electronic device 1 may include an opening area OA (or a first area) and a display area DA (or a second area) that at least partially surrounds the opening area OA. The electronic device 1 may include an intermediate area IA located between the opening area OA and the display area DA, and a peripheral area PA that surrounds the outside of the display area DA. The intermediate area IA and the peripheral area PA may each correspond to a non-display area that does not emit light.

The opening area OA may be located inside the display area DA. In an embodiment, as shown in FIG. 1, the opening area OA may be arranged in an upper left part of the display area DA. Alternatively, the opening area OA may be arranged in various positions. In an embodiment, for example, the opening area OA may be arranged in the center of an upper part of the display area DA or may be arranged in an upper right part thereof. “Left”, “right”, “upper”, and “lower” in a plan view of the present specification refer to directions when the electronic device 1 is viewed from a direction perpendicular to the electronic device 1, i.e., z direction. For example, “left” refers to a −x direction, “right” refers to a +x direction, “upper” refers to a +y direction, and “lower” refers to a −y direction. FIG. 1 shows an embodiment where a single opening area OA is arranged, but in an alternative embodiment, the opening area OA may include a plurality of opening areas.

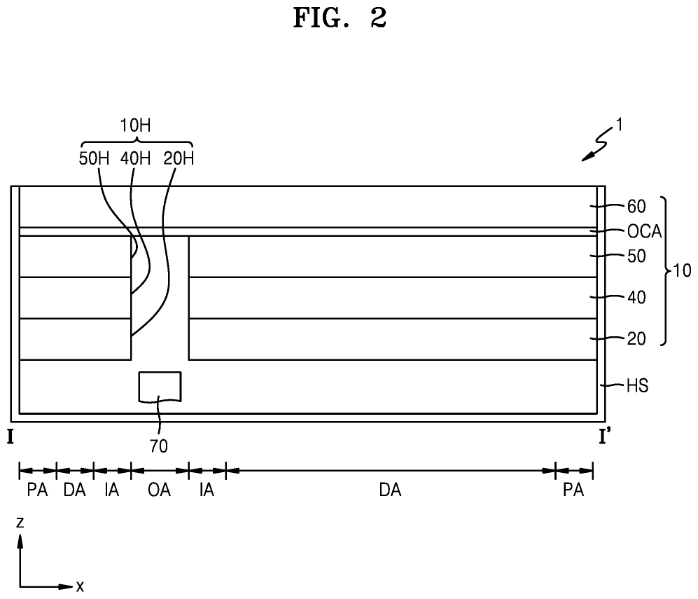

FIG. 2 is a schematic cross-sectional view of an electronic device according to an embodiment, taken along line I-I′ of FIG. 1.

Referring to FIG. 2, an embodiment of the electronic device 1 may include a display panel 10 and a component 70 arranged in the opening area OA of the display panel 10. The display panel 10 and the component 70 may be accommodated in a housing HS.

The display panel 10 may include a display layer 20, an input sensing layer 40, an optical functional layer 50, and a cover window 60.

The display layer 20 may include display elements (or light-emitting elements) that emit light to display an image, and pixel circuits that are connected to the display elements, respectively, to apply electrical signals to the display elements. Each of the display elements may include a light-emitting diode, for example, an organic light-emitting diode including an organic emission layer.

The input sensing layer 40 may obtain coordinate information corresponding to an external input, for example, a touch event. The input sensing layer 40 may include a sensing electrode (or a touch electrode) and trace lines connected to the sensing electrode. The input sensing layer 40 may be disposed above the display layer 20. The input sensing layer 40 may sense an external input by using a mutual capacitance method or/and a self-capacitance method.

The input sensing layer 40 may be directly formed on the display layer 20, or may be formed separately and then bonded to the display layer 20 through an adhesive layer, such as an optically-clear adhesive (OCA). In an embodiment, for example, a process for forming the input sensing layer 40 may be continuously performed after a process for forming the display layer 20, and in such an embodiment, an adhesive layer may not be located between the input sensing layer 40 and the display layer 20. FIG. 2 shows an embodiment where the input sensing layer 40 is located between the display layer 20 and the optical functional layer 50, but not being limited thereto. In an alternative embodiment, the input sensing layer 40 may be disposed above the optical functional layer 50.

The optical functional layer 50 may include a reflection prevention (or anti-reflection) layer. The reflection prevention layer may reduce reflectance of light (external light) incident on the display panel 10 through the cover window 60. In an embodiment, the reflection prevention layer may include a retarder and a polarizer. The retarder may be of a film type or a liquid crystal coating type. The polarizer may also be of a film type or a liquid crystal coating type. The polarizer of the film type may include a stretchable synthetic resin film, and the polarizer of the liquid crystal coating type may include liquid crystals arranged in a certain array.

In an alternative embodiment, the reflection prevention layer may include a black matrix and color filters. The color filters may be arranged in consideration of color of light emitted from each of light-emitting diodes. In another alternative embodiment, the reflection prevention layer may include a destructive interference structure. The destructive interference structure may include a first reflective layer and a second reflective layer, which are disposed on different layers. A first reflected ray and a second reflected ray respectively reflected from the first reflective layer and the second reflective layer may be destructively interfered, and accordingly, external light reflectance may be reduced.

The optical functional layer 50 may include a lens layer. The lens layer may increase light extraction efficiency of light emitted from the display layer 20, or may reduce color deviation. The lens layer may include a layer having a concave or convex lens shape, or/and may include a plurality of layers having different refractive indices from each other. The optical functional layer 50 may include both the reflection prevention layer and the lens layer, or may include only one of the reflection prevention layer and the lens layer.

The display panel 10 may be provided with an opening 10H, that is, the opening 10H is defined in the display panel 10. In an embodiment, as shown in FIG. 2, the display layer 20, the input sensing layer 40, and the optical functional layer 50 may be provided with first to third openings 20H, 40H, and 50H, respectively, and the first to third openings 20H, 40H, and 50H overlap each other to collectively defined the opening 10H.

The first opening 20H may be defined through the display layer 20 from an upper surface to a bottom surface thereof, the second opening 40H may be defined the input sensing layer 40 from an upper surface to a bottom surface thereof, and the third opening 50H may be defined through the optical functional layer 50 from an upper surface to a bottom surface thereof.

The first to third openings 20H, 40H, and 50H, included in the opening 10H, of the display panel 10 may be located to overlap each other in the opening area OA. The first to third openings 20H, 40H, and 50H may have the same or different sizes (or diameters) from each other.

In an alternative embodiment, at least one selected from the display layer 20, the input sensing layer 40, and the optical functional layer 50 may not be provided with any opening. In an embodiment, for example, one or two components selected from the display layer 20, the input sensing layer 40, and the optical functional layer 50 may not be provided with any opening.

The cover window 60 may be disposed over the optical functional layer 50. The cover window 60 may be bonded to the optical functional layer 50 through an adhesive layer, such as an OCA, located between the optical functional layer 50 and the cover window 60. The cover window 60 may include a glass material or a plastic material. In an embodiment, for example, the cover window 60 may include an ultra-thin glass window. F In an embodiment, for or example, the cover window 60 may include polyethersulfone, polyacrylate, polyether imide, polyethylene naphthalate, polyethylene terephthalate, polyphenylene sulfide, polyarylate, polyimide, polycarbonate, or cellulose acetate propionate.

The opening area OA may be a kind of component area (for example, a sensor area, a camera area, or a speaker area) in which the component 70 for adding various functions to the electronic device 1 is located. The component 70 may be disposed under the display panel 10 so as to overlap the opening 10H of the display panel 10.

The component 70 may include an electronic element. In an embodiment, for example, the component 70 may be an electronic element using light or sound. In an embodiment, for example, the electronic element may include a sensor that uses light such as an infrared sensor, a camera that receives light and captures an image, a sensor that outputs and senses light or sound to measure distance or recognizes a fingerprint or the like, a small lamp that outputs light, or a speaker that outputs sound. The electronic element using light may use light of various wavelength bands, such as visible light, infrared light, and ultraviolet light. The opening area OA corresponds a transmission area through which light or/and sound, which is output from the component 70 to the outside or travels from the outside toward the electronic element, may pass.

In an alternative embodiment, where the electronic device 1 is a smart watch or an instrument panel for a vehicle, the component 70 may be a member including the hands of a watch or a needle indicating certain information (for example, vehicle speed). In such an embodiment, the cover window 60 may include an opening located in the opening area OA so that the component 70, such as the needle, may be exposed to the outside. Alternatively, even when the electronic device 1 includes the component 70, such as a speaker, the cover window 60 may include an opening corresponding to the opening area OA.

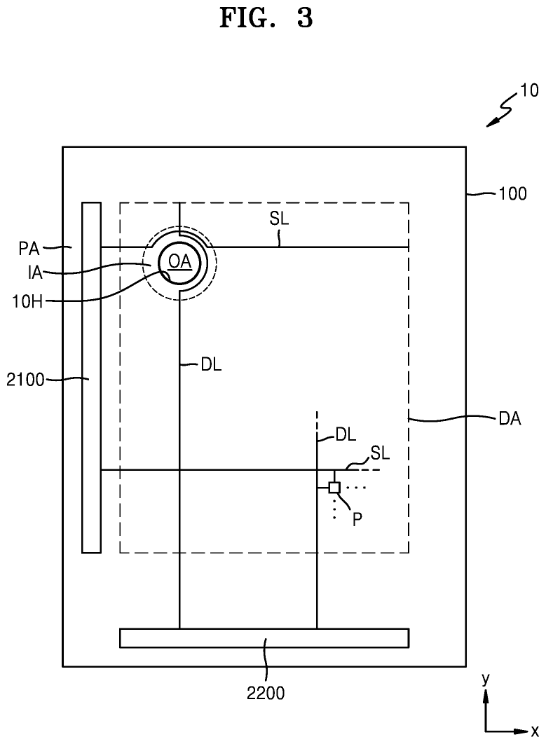

FIG. 3 is a schematic plan view of a display panel according to an embodiment.

Referring to FIG. 3, an embodiment of the display panel 10 may include the opening area OA, the display area DA, the intermediate area IA, and the peripheral area PA.

The display panel 10 includes a plurality of pixels P arranged in the display area DA. Each of the pixels P is a minimum (or unit) area from which light is emitted, and is an area from which red light, green light, or blue light is emitted. The display panel 10 may display an image by using light emitted from a light-emitting diode of each pixel P.

In an embodiment, each pixel P is a display element, and may include an organic light-emitting diode. In an alternative embodiment, the display panel 10 may include an inorganic light-emitting diode instead of an organic light-emitting diode. For convenience of description, hereinafter, embodiments where the pixel P includes an organic light-emitting diode as a display element will be described in detail. When the pixel P is arranged in the display area DA, it may indicate that an organic light-emitting diode OLED is arranged in the display area DA.

The intermediate area IA may surround the opening area OA. The intermediate area IA is where a display element, such as an organic light-emitting diode which emits light, is not arranged, and trace lines configured to provide signals to the pixels P provided around the opening area OA may pass through the intermediate area IA. In an embodiment, for example, as shown in FIG. 3, data lines DL and/or scan lines SL cross the display area DA in a y direction and/or an x direction, where portions of the data lines DL and/or scan lines SL may detour in the intermediate area IA along an edge of the opening 10H of the display panel 10, which is formed in the opening area OA.

A scan driver 2100, which provides a scan signal to each pixel P, a data driver 2200, which provides a data signal to each pixel P, and a first main power line (not shown) and a second main power line (not shown), which provides a first power voltage and a second power voltage, respectively, may be arranged in the peripheral area PA. FIG. 3 shows an embodiment where the data driver 2200 is arranged adjacent to one side of a substrate 100, but not being limited thereto. According to an alternative embodiment, the data driver 2200 may be disposed on a printed circuit board electrically connected to a pad arranged on one side of the display panel 10.

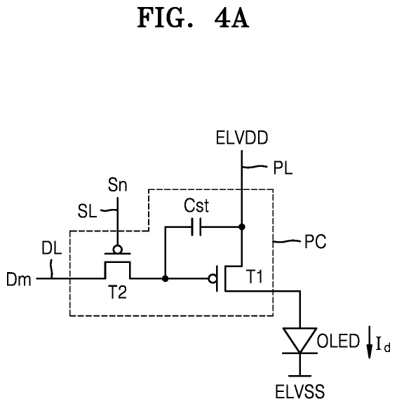

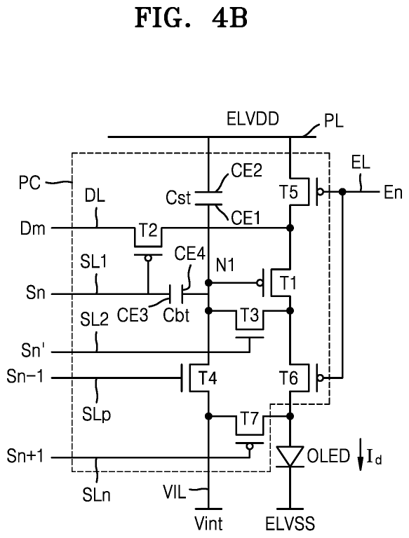

FIGS. 4A and 4B are schematic equivalent circuit diagrams of one pixel included in a display panel, according to embodiments.

Referring to FIG. 4A, in an embodiment, each pixel P may include a pixel circuit PC connected to a scan line SL, a data line DL, and a driving voltage line PL, and the organic light-emitting diode OLED connected to the pixel circuit PC. The pixel circuit PC may include a first transistor T1, a second transistor T2, and a storage capacitor Cst. The second transistor T2 may be a switching transistor. The second transistor T2 is connected to the scan line SL and the data line DL, and may be configured to transmit, to the first transistor T1, a data signal Dm input through the data line DL according to a scan signal Sn input through the scan line SL.

The storage capacitor Cst is connected to the second transistor T2 and the driving voltage line PL, and may store a voltage corresponding to a difference between a voltage received from the second transistor T2 and a first power voltage ELVDD (or a driving voltage) supplied to the driving voltage line PL.

The first transistor T1 may be a driving transistor. The first transistor T1 is connected to the driving voltage line PL and the storage capacitor Cst, and may be configured to control a driving current flowing from the driving voltage line PL to the organic light-emitting diode OLED, based on a voltage value stored in the storage capacitor Cst. The organic light-emitting diode OLED may emit light having a certain luminance corresponding to the driving current.

An opposite electrode (for example, a cathode) of the organic light-emitting diode OLED may receive a second power voltage ELVSS (or a common voltage). The organic light-emitting diode OLED may emit light by receiving a driving current I_{d} from the first transistor T1.

Referring to FIG. 4B, in an alternative embodiment, the pixel circuit PC may include first to seventh transistors T1, T2, T3, T4, T5, T6, and T7, the storage capacitor Cst, and a boost capacitor Cbt. In some embodiments, the pixel circuit PC may not include the boost capacitor Cbt, and hereinafter, an embodiment of the pixel circuit PC including the boost capacitor Cbt will be described.

Some of the first to seventh transistors T1, T2, T3, T4, T5, T6, and T7 may be n-channel metal-oxide-semiconductor field-effect transistors (MOSFETs) (hereinafter, will be referred to as “NMOS”), and others may be p-channel MOSFETs (hereinafter, will be referred to as “PMOS”). In an embodiment, for example, the third and fourth transistors T3 and T4 may be NMOS, and others may be PMOS, as shown in FIG. 4B. In an alternative embodiment, the third, fourth, and seventh transistors T3, T4, and T7 may be NMOS, and others may be PMOS. Alternatively, only one of the first to seventh transistors T1, T2, T3, T4, T5, T6, and T7 may be NMOS, and others may be PMOS.

The first to seventh transistors T1, T2, T3, T4, T5, T6, and T7, the storage capacitor Cst, and the boost capacitor Cbt may be connected to a signal line. The signal line may include a first scan line SL1 configured to transmit a first scan signal Sn, a second scan line SL2 configured to transmit a second scan signal Sn′, a previous scan line SLp configured to transmit a previous scan signal Sn−1, an emission control line EL configured to transmit an emission control signal En, a next scan line SLn configured to transmit a next scan signal Sn+1, and the data line DL intersecting with the first scan line SL1 and configured to transmit the data signal Dm.

The driving voltage line PL may be configured to transmit the first power voltage ELVDD to the first transistor T1, an initialization voltage line VIL may be configured to transmit an initialization voltage Vint for initializing a first gate electrode of the first transistor T1 and a pixel electrode of the organic light-emitting diode OLED.

The first transistor T1 may be a driving transistor. The first gate electrode (or a first control electrode) of the first transistor T1 may be connected to the storage capacitor Cst, a first electrode of the first transistor T1 may be electrically connected to the driving voltage line PL via the fifth transistor T5, and a second electrode of the first transistor T1 may be electrically connected to the pixel electrode of the organic light-emitting diode OLED via the sixth transistor T6. One of the first electrode and the second electrode of the first transistor T1 may be a source electrode, and the other of the first electrode and the second electrode of the first transistor T1 may be a drain electrode. The first transistor T1 may be configured to receive the data signal Dm based on a switching operation of the second transistor T2 and supply the driving current I_{d} to the organic light-emitting diode OLED.

The second transistor T2 may be a switching transistor. A second gate electrode (or a second control electrode) of the second transistor T2 is connected to the first scan line SL1, a first electrode of the second transistor T2 is connected to the data line DL, and a second electrode of the second transistor T2 is connected to the first electrode of the first transistor T1, and at the same time, is electrically connected to the driving voltage line PL via the fifth transistor T5. One of the first electrode and the second electrode of the second transistor T2 may be a source electrode, and the other of the first electrode and the second electrode of the second transistor T2 may be a drain electrode. The second transistor T2 may be configured to be turned on in response to the first scan signal Sn received through the first scan line SL1 to perform a switching operation of transmitting, to the first electrode of the first transistor T1, the data signal Dm transmitted to the data line DL.

The third transistor T3 may be a compensation transistor configured to compensate for a threshold voltage of the first transistor T1. A third gate electrode (or a compensation control electrode) of the third transistor T3 is connected to the second scan line SL2. A first electrode of the third transistor T3 is connected to a lower electrode CE1 of the storage capacitor Cst and the first gate electrode of the first transistor T1 through a first node N1.

The first node N1 may be an area where the first gate electrode of the first transistor T1, the first electrode of the third transistor T3, a second electrode of the fourth transistor T4, and a fourth electrode CE4 of the boost capacitor Cbt are connected to each other.

The first electrode of the third transistor T3 may be connected to the fourth transistor T4. A second electrode of the third transistor T3 is connected to the second electrode of the first transistor T1, and at the same time, is electrically connected to the pixel electrode of the organic light-emitting diode OLED via the sixth transistor T6. One of the first electrode and the second electrode of the third transistor T3 may be a source electrode, and the other of the first electrode and the second electrode of the third transistor T3 may be a drain electrode.

The third transistor T3 is configured to be turned on according to the second scan signal Sn′ received through the second scan line SL2 to electrically connect the first gate electrode of the first transistor T1 to the second electrode thereof to diode-connect the first transistor T1.

The fourth transistor T4 may be a first initialization transistor configured to initialize the first gate electrode of the first transistor T1. A fourth gate electrode (or a fourth control electrode) of the fourth transistor T4 is connected to the previous scan line SLp. A first electrode of the fourth transistor T4 is connected to the initialization voltage line VIL. A second electrode of the fourth transistor T4 may be connected to the lower electrode CE1 of the storage capacitor Cst, the first electrode of the third transistor T3, and the first gate electrode of the first transistor T1. One of the first electrode and the second electrode of the fourth transistor T4 may be a source electrode, and the other of the first electrode and the second electrode of the fourth transistor T4 may be a drain electrode. The fourth transistor T4 may be configured to be turned on in response to the previous scan signal Sn−1 received through the previous scan line SLp to perform an initialization operation of initializing the voltage of the first gate electrode of the first transistor T1 by transmitting the initialization voltage Vint to the first gate electrode of the first transistor T1.

The fifth transistor T5 may be an operation control transistor. A fifth gate electrode (or a fifth control electrode) of the fifth transistor T5 is connected to the emission control line EL, a first electrode of the fifth transistor T5 is connected to the driving voltage line PL, and a second electrode of the fifth transistor T5 is connected to the first electrode of the first transistor T1 and the second electrode of the second transistor T2. One of the first electrode and the second electrode of the fifth transistor T5 may be a source electrode, and the other of the first electrode and the second electrode of the fifth transistor T5 may be a drain electrode.

The sixth transistor T6 may be an emission control transistor. A sixth gate electrode (or a sixth control electrode) of the sixth transistor T6 is connected to the emission control line EL, a first electrode of the sixth transistor T6 is connected to the second electrode of the first transistor T1 and the second electrode of the third transistor T3, and a second electrode of the sixth transistor T6 is electrically connected to a second electrode of the seventh transistor T7 and the pixel electrode of the organic light-emitting diode OLED. One of the first electrode and the second electrode of the sixth transistor T6 may be a source electrode, and the other of the first electrode and the second electrode of the sixth transistor T6 may be a drain electrode.

The fifth transistor T5 and the sixth transistor T6 may be configured to be turned on at the same time in response to the emission control signal En received through the emission control line EL to transmit the first power voltage ELVDD to the organic light-emitting diode OLED to allow the driving current Id to flow through the organic light-emitting diode OLED.

The seventh transistor T7 may be a second initialization transistor configured to initialize the pixel electrode of the organic light-emitting diode OLED. A seventh gate electrode (or a seventh control electrode) of the seventh transistor T7 is connected to the next scan line SLn. A first electrode of the seventh transistor T7 is connected to the initialization voltage line VIL. The second electrode of the seventh transistor T7 is connected to the second electrode of the sixth transistor T6 and the pixel electrode of the organic light-emitting diode OLED. The seventh transistor T7 may be configured to be turned on according to the next scan signal Sn+1 received through the next scan line SLn to initialize the pixel electrode of the organic light-emitting diode OLED. FIG. 4B shows an embodiment where the seventh transistor T7 is connected to the next scan line SLn, but not being limited thereto. In an alternative embodiment, the seventh transistor T7 may be connected to the emission control line EL to be driven according to the emission control signal En.

The storage capacitor Cst includes the lower electrode CE1 and an upper electrode CE2. The lower electrode CE1 of the storage capacitor Cst is connected to the first gate electrode of the first transistor T1, and the upper electrode CE2 of the storage capacitor Cst is connected to the driving voltage line PL. The storage capacitor Cst may store a charge corresponding to a difference between the voltage of the first gate electrode of the first transistor T1 and the first power voltage ELVDD.

The boost capacitor Cbt includes a third electrode CE3 and the fourth electrode CE4. The third electrode CE3 may be connected to the second gate electrode of the second transistor T2 and the first scan line SL1, and the fourth electrode CE4 may be connected to the first node N1. The boost capacitor Cbt may increase the voltage of the first node N1 when the first scan signal Sn supplied to the first scan line SL1 is turned off, and when the voltage of the first node N1 is increased, black grayscale may be clearly expressed.

In an embodiment, as shown in FIG. 4B, the third and fourth transistors T3 and T4 are NMOS, and the first, second, and fifth to seventh transistors T1, T2, T5, T6, and T7 are PMOS. The first transistor T1, which directly affects the brightness of a display panel, is configured to include a semiconductor layer including polycrystalline silicon having a high reliability, and accordingly, a high-resolution display device may be implemented.

In an embodiment, since an oxide semiconductor has a high carrier mobility and a low leakage current, a voltage drop is not large even though a driving time is long. In other words, because a change in color of an image due to a voltage drop is not large even during low-frequency driving, the oxide semiconductor may be driven at low frequencies. As such, since the oxide semiconductor has a low leakage current, at least one selected from the third and fourth transistors T3 and T4 connected to the first gate electrode of the first transistor T1 is employed as an oxide semiconductor to prevent leakage current that may flow to the first gate electrode of the first transistor T1 and simultaneously reduce power consumption.

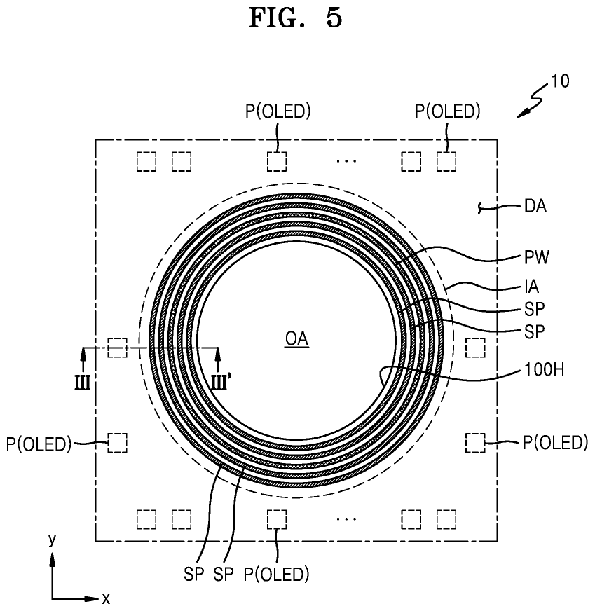

FIG. 5 is a plan view of an excerpt of a portion of a display panel of the disclosure.

The pixels P may be arranged in the display area DA, and the intermediate area IA may be located between the opening area OA and the display area DA. The pixels P may be arranged to surround the opening area OA and the intermediate area IA in the display area DA.

A position of the pixel P may correspond to a position of the organic light-emitting diode OLED. When the pixel P is arranged in the display area DA, it may indicate that the organic light-emitting diode OLED is arranged in the display area DA.

The pixels P adjacent to the opening area OA may be arranged apart from each other with respect to the opening area OA on a plane. The pixels P may be arranged apart from each other with respect to the opening area OA, or may be arranged apart from each other to the left and right of the opening area OA.

Separators SP may be arranged apart from each other in the intermediate area IA. Each of the separators SP may have a closed loop shape in a plan view (for example, when viewed from a direction substantially perpendicular to an upper surface of the substrate). In some embodiments, the separators SP may be arranged to form concentric circles as shown in FIG. 5.

At least one partition wall PW may be arranged in the intermediate area IA. A partition wall PW may have a closed loop shape in a plan view. In some embodiments, as shown in FIG. 5, one partition wall PW is located in the intermediate area IA, but not being limited thereto. In an alternative embodiment, two or more partition walls PW may be located apart from each other in the intermediate area IA.

The separators SP may be located between the display area DA and the partition wall PW and/or between the partition wall PW and the opening area OA. In some embodiments, as shown in FIG. 5, two separators SP are located between the display area DA and the partition wall PW, and two separators SP are located between the partition wall PW and the opening area OA, but the disclosure is not limited thereto. In an alternative embodiment, one separator SP or three or more separators SP may be located between the display area DA and the partition wall PW. In an alternative embodiment, one separator SP or three or more separators SP may be located between the partition wall PW and the opening area OA.

Since a substrate of the display panel 10 is provided with a through hole 100H corresponding to the opening area OA, the opening area OA may refer to the through hole 100H of the substrate in the present specification. In an embodiment, for example, when the separators SP are located between the partition wall PW and the opening area OA, it may indicate that the separators SP are located between the partition wall PW and the through hole 100H.

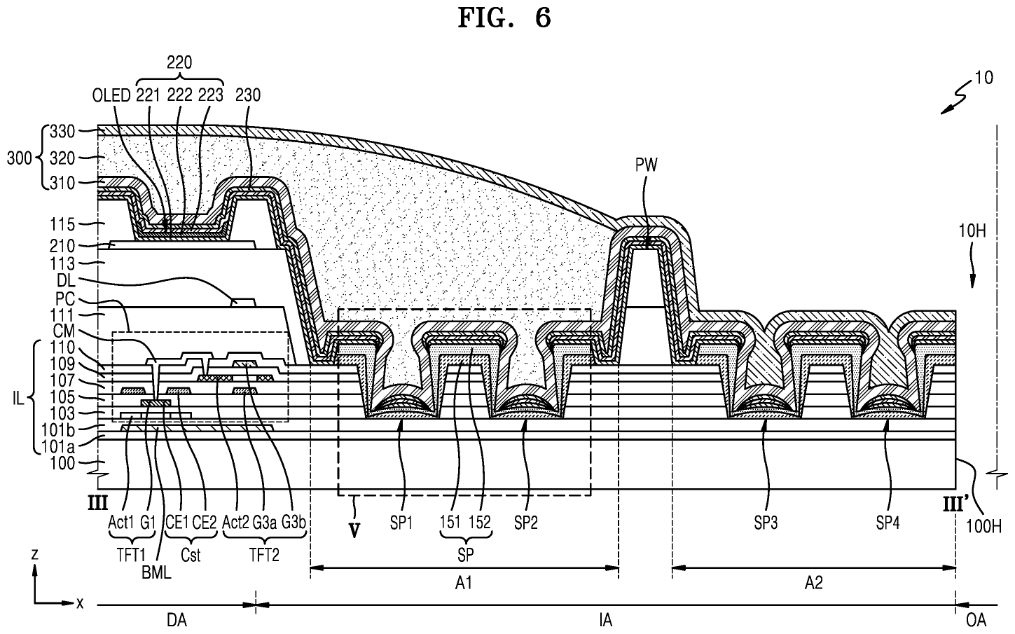

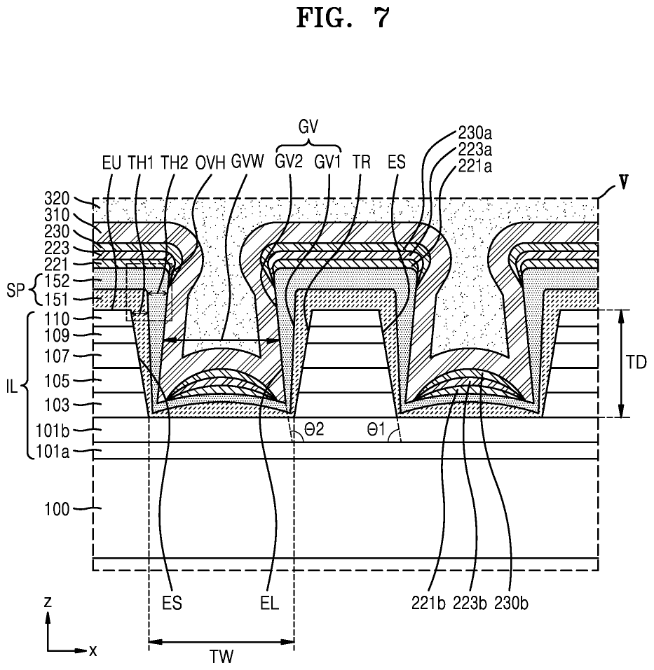

FIG. 6 is a cross-sectional view of a portion of a display panel according to an embodiment taken along line III-III′ of FIG. 5, and FIG. 7 is an enlarged cross-sectional view of an area V of FIG. 6.

FIG. 7 shows a structure of the separators SP located in a first area A1 between the display area DA and the partition wall PW, but separators SP located in a second area A2 between the partition wall PW and the opening area OA may also have the same structure as the structure of the separators SP located in the first area A1.

Referring to FIG. 6, an embodiment of the display panel 10 may include the display area DA, the opening area OA, and the intermediate area IA therebetween. The display panel 10 includes the substrate 100 in which components of the display panel 10 are arranged, and the substrate 100 includes the display area DA, the opening area OA, and the intermediate area IA therebetween.

The pixel circuit PC may be disposed on the display area DA of the substrate 100, and the organic light-emitting diode OLED electrically connected to the pixel circuit PC may be disposed over the pixel circuit PC.

The substrate 100 may include a glass material or polymer resin. In an embodiment, for example, the polymer resin may include polyethersulfone, polyacrylate, polyether imide, polyethylene naphthalate, polyethylene terephthalate, polyphenylene sulfide, polyarylate, polyimide, polycarbonate, or cellulose acetate propionate. The substrate 100 including polymer resin may be flexible, rollable, and bendable. The substrate 100 may have a multilayer structure including a layer including the polymer resin and an inorganic layer (not shown).

A first buffer layer 101a and a second buffer layer 101b may be disposed on an upper surface of the substrate 100. The first buffer layer 101a and the second buffer layer 101b may prevent penetration of impurities into a first semiconductor layer Act1 of the pixel circuit PC. Each of the first buffer layer 101a and the second buffer layer 101b may include an inorganic insulating material, such as silicon nitride, silicon oxynitride, or silicon oxide, and may be defined by a single layer or a multilayer, each layer therein including at least one selected from the aforementioned inorganic insulating materials.

A lower metal layer BML may be located between the first buffer layer 101a and the second buffer layer 101b. The lower metal layer BML may block external light from reaching a first thin-film transistor TFT1 and/or a second thin-film transistor TFT2. In some embodiments, a constant voltage or a signal is applied to the lower metal layer BML to prevent damage to the pixel circuit PC due to electrostatic discharge. FIG. 6 shows an embodiment where one lower metal layer BML is disposed under the pixel circuit PC, but not being limited thereto. In some embodiments, the lower metal layer BML may include a plurality of lower metal layers. The lower metal layer BML may include a metal material. In an embodiment, for example, the lower metal layer BML may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be defined by a single layer or a multilayer, each layer therein including at least one selected from the aforementioned materials.

The pixel circuit PC may be disposed on the second buffer layer 101b. The pixel circuit PC may include a plurality of transistors and the storage capacitor Cst. FIG. 6 illustrates the first thin-film transistor TFT1 and the second thin-film transistor TFT2 of the pixel circuit PC.

The first thin-film transistor TFT1 may include the first semiconductor layer Act1 on the second buffer layer 101b and a first gate electrode G1 overlapping a channel region of the first semiconductor layer Act1. The first semiconductor layer Act1 may include a silicon-based semiconductor material, for example, polysilicon. The first semiconductor layer Act1 may include the channel region and impurity regions arranged at both sides of the channel region. One of the impurity regions arranged at opposing sides of the channel region may be a source region, and the other of the impurity regions may be a drain region.

A first gate insulating layer 103 may be located between the first semiconductor layer Act1 and the first gate electrode G1. The first gate insulating layer 103 may include an inorganic insulating material, such as silicon oxide, silicon nitride, or silicon oxynitride, and may have a single-layered or multilayer structure including the aforementioned inorganic insulating materials.

The first gate electrode G1 may include a conductive material including Mo, Al, Cu, or Ti, and may have a single-layered or multilayer structure including at least one selected from the aforementioned materials.

The storage capacitor Cst may include the lower electrode CE1 and the upper electrode CE2, overlapping each other. In an embodiment, the lower electrode CE1 of the storage capacitor Cst may include the first gate electrode G1 of the first thin-film transistor TFT1. In an embodiment, for example, the first gate electrode G1 of the first thin-film transistor TFT1 may be integrally formed with the lower electrode CE1 of the storage capacitor Cst as a single unitary and indivisible part.

The upper electrode CE2 of the storage capacitor Cst may include a conductive material including Mo, Al, Cu, or Ti, and may have a single-layered or multilayer structure including at least one selected from the aforementioned materials.

A first interlayer insulating layer 105 may be located between the lower electrode CE1 and the upper electrode CE2 of the storage capacitor Cst, and a second interlayer insulating layer 107 may be disposed on the upper electrode CE2 of the storage capacitor Cst. Each of the first interlayer insulating layer 105 and the second interlayer insulating layer 107 may include an inorganic insulating material, such as silicon oxide, silicon nitride, or silicon oxynitride, and may have a single-layered or multilayer structure including at least one selected from the aforementioned inorganic insulating materials.

A second semiconductor layer Act2 of the second thin-film transistor TFT2 may be disposed on the second interlayer insulating layer 107. The second semiconductor layer Act2 may include an oxide-based semiconductor material. In an embodiment, for example, the second semiconductor layer Act2 may include a Zn oxide-based material, for example, In—Zn oxide or Ga—In—Zn oxide. In some embodiments, the second semiconductor layer Act2 may be an In—Ga—Zn—O (IGZO), In—Sn—Zn—O (ITZO), or In—Ga—Sn—Zn—O (IGTZO) semiconductor containing a metal, such as indium (In), gallium (Ga), or Tin (Sn), in zinc oxide (ZnO).

In some embodiments, the second thin-film transistor TFT2 may have a double gate structure including a lower gate electrode G3a and an upper gate electrode G3b, overlapping a channel region of the second semiconductor layer Act2. In some embodiments, the lower gate electrode G3a may be omitted.

The lower gate electrode G3a may be disposed in (or directly on) a same layer as the upper electrode CE2 of the storage capacitor Cst. In an embodiment, for example, the lower gate electrode G3a may be located between the first interlayer insulating layer 105 and the second interlayer insulating layer 107. The lower gate electrode G3a may include a same material as the upper electrode CE2 of the storage capacitor Cst.

The upper gate electrode G3b may be disposed over the second semiconductor layer Act2 with a second gate insulating layer 109 therebetween. The upper gate electrode G3b may include a conductive material including Mo, Al, Cu, or Ti, and may have a single-layered or multilayer structure including at least one selected from the aforementioned materials. The second gate insulating layer 109 may include an inorganic insulating material, such as silicon oxide, silicon nitride, or silicon oxynitride, and may have a single-layered or multilayer structure including at least one selected from the aforementioned inorganic insulating materials.

A third interlayer insulating layer 110 may be disposed on the upper gate electrode G3b. The third interlayer insulating layer 110 may include an inorganic insulating material, such as silicon oxide, silicon nitride, or silicon oxynitride, and may have a single-layered or multilayer structure including at least one selected from the aforementioned inorganic insulating materials.

FIG. 6 shows an embodiment where the upper electrode CE2 of the storage capacitor Cst is disposed in a same layer as the lower gate electrode G3a of the second thin-film transistor TFT2, but the disclosure is not limited thereto. In an alternative embodiment, the upper electrode CE2 of the storage capacitor Cst may be disposed in a same layer as the second semiconductor layer Act2 of the second thin-film transistor TFT2.

The first thin-film transistor TFT1 and the second thin-film transistor TFT2 may be electrically connected to each other through a connection electrode CM. The connection electrode CM may be disposed on the third interlayer insulating layer 110. One side of the connection electrode CM may be connected to the first gate electrode G1 of the first thin-film transistor TFT1, and the other side of the connection electrode CM may be connected to the second semiconductor layer Act2 of the second thin-film transistor TFT2.

The connection electrode CM may include a conductive material including Mo, Al, Cu, or Ti, and may have a single-layered or multilayer structure including at least one selected from the aforementioned materials. In an embodiment, for example, the connection electrode CM may have a multilayer structure including titanium layer/aluminum layer/titanium layer (Ti/Al/Ti).

A first planarization layer 111 may be disposed on the connection electrode CM. In some embodiments, the first planarization layer 111 may include an organic insulating material. The organic insulating material may include benzocyclobutene (BCB), polyimide, or hexamethyldisiloxane (HMDSO).

A signal line, such as the data line DL, may be disposed on the first planarization layer 111 and may be covered with a second planarization layer 113. FIG. 6 shows an embodiment where the data line DL is disposed on the first planarization layer 111, but the disclosure is not limited thereto. In an alternative embodiment, the data line DL may be disposed in a same layer as the connection electrode CM, for example, on the third interlayer insulating layer 110.

The data line DL may include a conductive material including Mo, Al, Cu, or Ti, and may have a single-layered or multilayer structure including at least one selected from the aforementioned materials. In an embodiment, for example, the data line DL may have a multilayer structure including titanium layer/aluminum layer/titanium layer (Ti/Al/Ti).

The second planarization layer 113 may include an organic insulating material. The organic insulating material may include BCB, polyimide, or HMDSO.

The organic light-emitting diode OLED may include a pixel electrode 210, an intermediate layer 220 on the pixel electrode 210, and an opposite electrode 230 on the intermediate layer 220.

The pixel electrode 210 may be disposed on the second planarization layer 113. In an embodiment, the pixel electrode 210 may include a reflective film including Ag, Mg, Al, Pt, Pd, Au, Ni, Nd, Ir, Cr, or a compound thereof. In an alternative embodiment, the pixel electrode 210 may further include a conductive oxide layer over and/or under the reflective film. The conductive oxide layer may include an indium tin oxide (ITO), indium zinc oxide (IZO), ZnO, indium oxide (In₂O₃), indium gallium oxide (IGO), and/or aluminum zinc oxide (AZO). In an embodiment, the pixel electrode 210 may have a three-layer structure of ITO layer/Ag layer/ITO layer.

An edge of the pixel electrode 210 may overlap a bank layer 115. The bank layer 115 may be provided with a pixel opening overlapping a portion of the pixel electrode 210. The bank layer 115 may include an organic insulating material, such as BCB, polyimide, or HMDSO. In some embodiments, the bank layer 115 may include a light-blocking material. The light-blocking material may include resin or paste including carbon black, carbon nanotubes, or black dye, metal particles, such as Ni, Al, Mo or an alloy thereof, metal oxide particles (for example, chromium oxide), or metal nitride particles (for example, chromium nitride).

The intermediate layer 220 may include an emission layer 222 overlapping the pixel electrode 210 through an emission opening defined in the bank layer 115. The emission layer 222 may include a polymer or low molecular weight organic material which emits red light, green light, or blue light. In some embodiments, the emission layer 222 may include an inorganic material or quantum dots.

The intermediate layer 220 may include a first functional layer 221 and/or a second functional layer 223. The first functional layer 221 may include a hole transport layer (HTL) and/or a hole injection layer (HIL). The second functional layer 223 may include an electron transport layer (ETL) and/or an electron injection layer (EIL).

In some embodiments, the emission layer 222 may be patterned to correspond to the pixel electrode 210, and the first functional layer 221 and/or the second functional layer 223 may be integrally or commonly provided with respect to the entire surface of the display area DA. In such embodiments, the first functional layer 221 and the second functional layer 223 may extend to the intermediate area IA.

The opposite electrode 230 may include a conductive material having a low work function. In an embodiment, for example, the opposite electrode 230 may include a (semi)transparent layer including Ag, Mg, Al, Pt, Pd, Au, Ni, Nd, Ir, Cr, lithium (Li), Ca, or an alloy thereof. Alternatively, the opposite electrode 230 may further include a layer including ITO, IZO, ZnO, and/or In₂O₃ on the (semi)transparent layer.

An encapsulation layer 300 may be disposed on the organic light-emitting diode OLED and may seal the organic light-emitting diode OLED. The encapsulation layer 300 may include an inorganic encapsulation layer and an organic encapsulation layer. In an embodiment, as shown in FIG. 6, the encapsulation layer 300 includes first and second inorganic encapsulation layers 310 and 330 and an organic encapsulation layer 320 located therebetween.

Each of the first inorganic encapsulation layer 310 and the second inorganic encapsulation layer 330 may include at least one inorganic material selected from aluminum oxide, titanium oxide, tantalum oxide, hafnium oxide, zinc oxide, silicon oxide, silicon nitride, and silicon oxynitride. Each of the first inorganic encapsulation layer 310 and the second inorganic encapsulation layer 330 may be defined by a single layer or a multilayer, each layer therein including at least one selected from the aforementioned materials.

The organic encapsulation layer 320 may include a polymer-based material. The polymer-based material may include acrylic resin, epoxy-based resin, polyimide, or polyethylene. In an embodiment, the organic encapsulation layer 320 may include acrylate.

Insulating layers including an inorganic insulating material, which are stacked on the substrate 100, may be referred to as an inorganic insulating layer IL. In an embodiment, for example, FIG. 6 shows that the inorganic insulating layer IL includes the first buffer layer 101a to the third interlayer insulating layer 110, but the disclosure is not limited thereto. In an alternative embodiment, for example, at least one selected from the first buffer layer 101a, the second buffer layer 101b, the first gate insulating layer 103, the first interlayer insulating layer 105, the second interlayer insulating layer 107, the second gate insulating layer 109, and the third interlayer insulating layer 110 may be omitted.

Referring to the intermediate area IA in FIG. 6, at least a portion of the inorganic insulating layer IL of the display area DA may extend toward the through hole 100H of the substrate 100. In other words, at least a portion of the inorganic insulating layer IL may be arranged in the display area DA and the intermediate area IA. In an embodiment, for example, an edge of the inorganic insulating layer IL, facing the opening area OA, may be located on substantially the same vertical line as an edge of the substrate 100, defining the through hole 100H.

An edge of the first planarization layer 111 and an edge of the second planarization layer 113 may be arranged in the intermediate area IA. In an embodiment, for example, the edge of the first planarization layer 111 and the edge of the second planarization layer 113 may be located between the display area DA and the separator SP located closest to the display area DA among the separators SP arranged in the intermediate area IA. The intermediate area IA may include the first area A1 from the edge of the second planarization layer 113 to the partition wall PW, and the second area A2 from the partition wall PW to the through hole 100H.

In an embodiment, as shown in FIG. 7, the inorganic insulating layer IL may include or define at least one trench TR surrounding the opening area OA. In a plan view, trenches TR have a closed loop shape and may be arranged apart from each other. In the present specification, each of the trenches TR may refer to an area in which a portion of the inorganic insulating layer IL are removed in a thickness direction (−z direction) and a portion thereof remains. In an embodiment, as shown in FIG. 7, portions of the first gate insulating layer 103, the first interlayer insulating layer 105, the second interlayer insulating layer 107, the second gate insulating layer 109, and the third interlayer insulating layer 110 may be removed to form a side surface of the trench TR. The side surface of the trench TR may refer to a side surface ES of the inorganic insulating layer IL, defining the trench TR. In an embodiment, the side surface ES of the inorganic insulating layer IL may be forward tapered, that is, the side surface ES of the inorganic insulating layer IL defining the trench TR is inclined in a way such that a width of the trench TR decreases as being toward the upper surface of the substrate 100. A first angle θ1 formed by the side surface ES of the inorganic insulating layer IL and the upper surface of the substrate 100 may be less than or equal to 90 degrees.

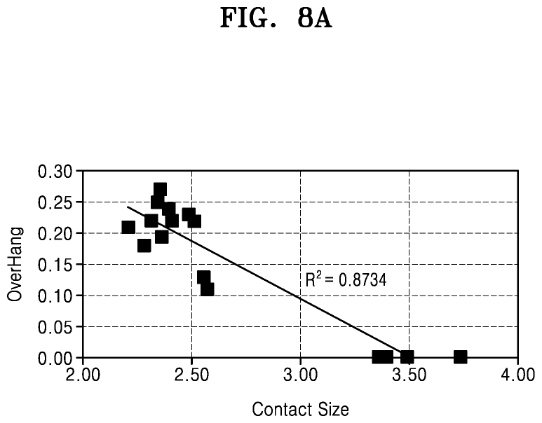

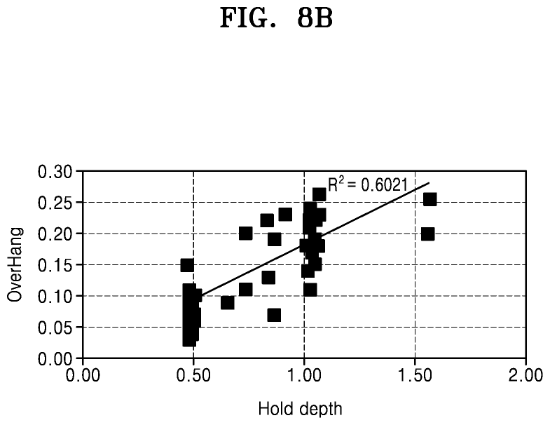

FIG. 7 shows an embodiment where the second buffer layer 101b constitutes a bottom surface of the trench TR, but the disclosure is not limited thereto. In an embodiment, a layer constituting the bottom surface of the trench TR may vary depending on a depth TD of the trench TR. The depth TD and a width TW of the trench TR will be described in detail with reference to FIGS. 8A and 8B.

The separators SP may be arranged to cover an upper surface EU and the side surface ES of the inorganic insulating layer IL defining the trench TR. The separators SP may be arranged to correspond to the trenches TR apart from each other. In an embodiment, for example, a first separator SP1 and a second separator SP2 may be arranged to correspond to the trenches TR arranged in the first area A1 and apart from each other.

The separator SP may have a protrusion OVH at a corner portion where the upper surface EU and the side surface ES of the inorganic insulating layer IL meet each other. The corner portion may refer to an entrance of the trench TR. The side surface ES of the inorganic insulating layer IL may refer to an inner surface of the inorganic insulating layer IL, in which a portion of the inorganic insulating layer IL is removed to define the trench TR.

The protrusion OVH may be provided by a difference in thickness of the separator TS on the upper surface EU and the side surface ES of the inorganic insulating layer IL. The separator SP may be deposited by using a sputtering process. In other words, the separator SP may be formed by sputtering a material constituting the separator SP at a position corresponding to the trench TR of the inorganic insulating layer IL. Due to characteristics of the process, the material constituting the separator SP may be deposited relatively thicker on the upper surface EU of the inorganic insulating layer IL than on the side surface ES thereof. In other words, it may be relatively difficult for the material constituting the separator SP to be deposited inside the trench TR. In addition, deposition may be more difficult in a depthwise direction (for example, −z direction) of the trench TR. Accordingly, the separator SP may include the protrusion OVH, protruding toward the inside or the center of the trench TR, at the entrance of the trench TR.

A second angle θ2 formed by an inclined surface EL of the separator, located inside the trench TR, and the upper surface of the substrate 100 by the protrusion OVH may have a greater value than the first angle θ1 formed by the side surface ES of the inorganic insulating layer IL and the upper surface of the substrate 100. The second angle θ2 may be greater than or equal to 90 degrees. In other words, the inclined surface EL of the separator SP, located inside the trench TR, may be reversely tapered by the protrusion OVH.

The separator SP may include a stack of a plurality of layers. In an embodiment, the separator SP may include a stack of a first metal layer 151 and a second metal layer 152, as shown in FIG. 7. The separator SP may be formed by depositing the first metal layer 151 on the inorganic insulating layer IL and then depositing the second metal layer 152 on the first metal layer 151. As described above, due to characteristics of a deposition process, such as sputtering, the first metal layer 151 may be deposited in a protruded form in the vicinity of the entrance of the trench TR. Since the second metal layer 152 is deposited along a structure of the first metal layer 151 as a lower structure, the protruded form in the vicinity of the entrance of the trench TR may be maximized. In addition, stress of the metal layer may be alleviated by dividing the separator SP into a plurality of layers and depositing the plurality of layers, compared to a case where only one metal layer is deposited thickly to form the separator SP.

In an embodiment, the separator SP may further include a third metal layer (not shown). The third metal layer may be disposed on the second metal layer 152. The third metal layer may be deposited along a structure of the second metal layer 152 as a lower structure. In such an embodiment, the separator SP may include three metal layers. Accordingly, the separator SP may be provided in a further protruded form in the vicinity of the entrance of the trench TR.

In an embodiment, each of the first metal layer 151 and the second metal layer 152 may be formed together with at least one selected from the connection electrode CM, the data line DL, and the pixel electrode 210, described with reference to FIG. 6, in a same process.

In an embodiment, for example, the first metal layer 151 may be formed together with the connection electrode CM in a same process, and the second metal layer 152 may be formed together with the data line DL in a same process. In such an embodiment, the third metal layer may be formed together with the pixel electrode 210 in a same process.

Each of the first metal layer 151 and the second metal layer 152 may include a conductive material including molybdenum, aluminum, copper, or titanium, and may have a single-layered or multilayer structure including at least one selected from the conductive materials listed above. In an embodiment, for example, each of the first metal layer 151 and the second metal layer 152 may have a multilayer structure including titanium layer/aluminum layer/titanium layer (Ti/Al/Ti). The third metal layer may include a reflective film including Ag, Mg, Al, Pt, Pd, Au, Ni, Nd, Ir, Cr, or a compound thereof. In an alternative embodiment, the pixel electrode 210 may further include a conductive oxide layer over and/or under the reflective film. In an embodiment, the pixel electrode 210 may have a three-layer structure of ITO layer/Ag layer/ITO layer.

In an embodiment, the separator SP may include or define a groove GV. The groove GV may overlap the trench TR of the inorganic insulating layer IL. As the separator SP is stacked along the shape of the trench TR, the groove GV may have a shape in which the separator SP is bent toward the substrate 100. When the separator SP includes the protrusion OVH, it may indicate that a width GVW of the groove GV increases toward the substrate 100. Alternatively, it may be understood that the thickness of the separator SP in the groove GV decreases as being toward the substrate 100. The inclined surface EL of the separator SP, defining the groove GV, may be reversely tapered, that is, the inclined surface EL of the separator SP inside the trench TR is inclined in a way such that a width of the groove GV defined by the inclined surface EL of the separator SP increases as being toward the upper surface of the substrate 100.

In an embodiment, the first metal layer 151 may include a first groove GV1, and the second metal layer 152 may include a second groove GV2. The groove GV of the separator SP may have a shape in which the first groove GV1 and the second groove GV2 are overlappingly stacked. In the first groove GV1, a first thickness TH1 of first metal layer 151 may decrease as being toward the substrate 100. In the second groove GV2, a second thickness TH2 of the second metal layer 152 may decrease as being toward the substrate 100. Each of the first thickness TH1 and the second thickness TH2 may be at least about 0.01 micrometer (μm) and not more than about 0.45 μm, that is, in a range of about 0.01 μm to about 0.45 μm. Each of the first metal layer 151 and the second metal layer 152 in an area (for example, the upper surface EU of the inorganic insulating layer IL) other than the first groove GV1 and the second groove GV2 may have a thickness of about 0.6 μm.

The first functional layer 221, the separator SP, and the opposite electrode 230 may be disposed on the separator SP. Since the first functional layer 221, the second functional layer 223, and the opposite electrode 230 are stacked along a structure of the separator SP as their lower structure, the first functional layer 221, the second functional layer 223, and the opposite electrode 230 may have separate portions apart from each other due to the protrusion OVH of the separator SP.

In an embodiment, for example, the first functional layer 221 and the second functional layer 223 may include first and second portions 221a and 221b and first and second portions 223a and 223b, respectively, where the first portions 221a and 223a are arranged outside the trench TR, and the second portions 221b and 223b are separated from the first portions 221a and 223a by the separator SP. In such an embodiment, the opposite electrode 230 may include a first portion 230a arranged outside the trench TR and a second portion 230b separated from the first portion 230a by the separator SP. The second portion 221b of the first functional layer 221, the second portion 223b of the second functional layer 223, and the second portion 230b of the opposite electrode 230 may each be disposed on the bottom surface of the trench TR.

Since the first functional layer 221 and the second functional layer 223, each including an organic material, are separated by the separators SP in the intermediate area IA, impurities, such as moisture, flowing through the through hole 100H of the substrate 100 may be effectively prevented from traveling to the organic light-emitting diode OLED through the first functional layer 221 and the second functional layer 223.

Referring to FIGS. 6 and 7, the encapsulation layer 300 may extend to the intermediate area IA. The first inorganic encapsulation layer 310 has a relatively high step coverage characteristics, and thus, may entirely and continuously overlap the separator SP. In an embodiment, for example, the first inorganic encapsulation layer 310 may continuously extend along the groove GV of the separator SP.

FIGS. 8A and 8B are graphs of the width and depth of a trench formed in an inorganic insulating layer. The shape of the protrusion OVH or the groove GV of the separator SP may be affected by the width TW and depth TD of the trench as well as a material forming the separator SP. FIGS. 8A and 8B show data for a structure in which the separator SP includes the first metal layer 151 and the second metal layer 152, each having a Ti/Al/Ti structure, and each of the first metal layer 151 and the second metal layer 152 may have a thickness of about 0.6 μm on the upper surface EU of the inorganic insulating layer IL.

In an embodiment, the width TW of the trench TR may be less than or equal to 3.5 μm, and the depth TD of the trench TR may be greater than or equal to 0.5 μm.

In the graph of FIG. 8A, an x-axis represents the width TW of the trench TR as a contact size, and a y-axis represents a protrusion size as an overhang value. In the graph of FIG. 8B, an x-axis represents the depth TD of the trench TR as a hole depth, and a y-axis represents a protrusion size as an overhang value. When the overhang value is greater than or equal to 0.10 μm, it indicates that the protrusion OVH exists. The width TW may refer to the width of the bottom surface of the trench TR, and the depth TD may refer to a vertical distance between the upper surface EU of the inorganic insulating layer IL, on which the trench TR is formed, and the bottom surface of the trench TR.

Referring to FIG. 8A, as the width TW of the trench TR decreases, the overhang value tends to increase. In other words, as the width TW of the trench TR decreases, the protrusion OVH of the separator SP may be easily formed.

When the width TW of the trench TR is about 2.5 μm, the overhang value is greater than or equal to 0.10 μm, but when the width TW of the trench TR is about 3.5 μm, the overhang value is less than or equal to 0.05 μm. In other words, when the width TW of the trench TR is less than or equal to 3.5 μm, the protrusion OVH of the separator SP may be easily formed. A minimum value of the width TW of the trench TR may be determined based on a deposition thickness of the separator SP. Under the aforementioned experimental conditions, as the width TW of the trench TR is greater than or equal to about 1.0 μm, the inclined surfaces EL of the separator SP may not be in contact with each other in the trench TR.

In an embodiment, the width TW of the trench TR may be about twice the sum of the thickness of the first metal layer 151 on the upper surface EU of the inorganic insulating layer IL and the thickness of the second metal layer 152 on the upper surface EU of the inorganic insulating layer IL.

Referring to FIG. 8B, as the depth TD of the trench TR increases, the overhang value tends to increase. In other words, as the depth TD of the trench TR increases, the protrusion OVH of the separator SP may be easily formed.

When the depth TD of the trench TR is about 0.50 μm, the overhang value is less than or equal to about 0.10 μm, and thus, when the depth TD of the trench TR is greater than or equal to 0.50 μm, the protrusion OVH of the separator SP may be easily formed. A maximum value of the depth TD of the trench TR may be determined by the total thickness of the inorganic insulating layer IL.

In an embodiment, the depth TD of the trench TR may be greater than a value of the sum of the thickness of the first metal layer 151 on the upper surface EU of the inorganic insulating layer IL, the thickness of the second metal layer 152 on the upper surface EU of the inorganic insulating layer IL, and the thickness of the intermediate layer 220.

In an embodiment, the depth TD of the trench TR may be defined by an etch stopper (not shown). The etch stopper may define the bottom surface of the trench TR when a portion of the inorganic insulating layer IL is etched to form the trench TR. The etch stopper may be disposed in a same layer as the lower metal layer BML, the first semiconductor layer Act1 of the first thin-film transistor TFT1, the first gate electrode G1 of the first thin-film transistor TFT1, the second semiconductor layer Act2 of the second thin-film transistor TFT2, or the upper gate electrode G3b of the second thin-film transistor TFT2.

According to an embodiment as described above, a display panel having an area in which various types of components may be arranged in a display area and simultaneously having improved reliability, and an electronic device including the display panel may be implemented.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display panel comprising:
a substrate comprising an opening area, a display area surrounding at least a portion of the opening area, and an intermediate area between the opening area and the display area;
a light-emitting diode disposed on the display area, and comprising a pixel electrode, an opposite electrode, and an intermediate layer between the pixel electrode and the opposite electrode;
an inorganic insulating layer disposed on the intermediate area, and defining a trench surrounding the opening area; and
a separator disposed on an upper surface of the inorganic insulating layer and a side surface of the inorganic insulating layer, the side surface defining the trench, in the intermediate area, wherein the separator includes a protrusion at a corner portion of the inorganic insulating layer where the upper surface meets the side surface.

2. The display panel of claim 1, wherein the protrusion protrudes toward an inside of the trench.

3. The display panel of claim 1, wherein an inclined surface of the separator, located inside the trench, is reversely tapered by the protrusion.

4. The display panel of claim 1, wherein the side surface of the inorganic insulating layer, defining the trench, is forward tapered.

5. The display panel of claim 1, wherein the separator comprises a plurality of metal layers.

6. The display panel of claim 1, wherein a width of the trench is less than or equal to 3.5 μm.

7. The display panel of claim 1, wherein a depth of the trench is greater than or equal to 0.5 μm.

8. The display panel of claim 1, wherein the intermediate layer comprises:
an emission layer disposed to correspond to the pixel electrode; and
a functional layer extending from the display area to the intermediate area,
wherein the functional layer is disposed on the separator.

9. The display panel of claim 8, wherein the functional layer comprises:
a first portion disposed outside the trench; and
a second portion disposed inside the trench and separated from the first portion.

10. The display panel of claim 1, wherein the opposite electrode comprises:
a first portion disposed outside the trench; and
a second portion disposed inside the trench and separated from the first portion.

11. An electronic device comprising:
a display panel comprising an opening area, a display area surrounding at least a portion of the opening area, and an intermediate area between the opening area and the display area; and
a component disposed to overlap the opening area of the display panel
wherein the display panel comprises:
a substrate;
a light-emitting diode disposed on the substrate to overlap the display area and comprising a pixel electrode, an opposite electrode, and an intermediate layer between the pixel electrode and the opposite electrode;
an inorganic insulating layer disposed on the substrate to overlap the intermediate area and defining a trench surrounding the opening area; and
a separator disposed on the substrate to overlap the intermediate area and defining a groove overlapping the trench,
wherein a width of the groove increases as being toward the substrate.

12. The electronic device of claim 11, wherein an inclined surface of the separator, defining the groove, is reversely tapered.

13. The electronic device of claim 11, wherein the separator comprises:
a first metal layer defining a first groove; and
a second metal layer disposed on the first metal layer and defining a second groove,
wherein the first groove and the second groove overlap each other.

14. The electronic device of claim 13, wherein each of a first thickness of the first metal layer in the first groove and a second thickness of the second metal layer in the second groove decreases as being toward the substrate.

15. The electronic device of claim 14, wherein each of the first thickness and the second thickness is in a range of about 0.01 μm to about 0.45 μm.

16. The electronic device of claim 11, wherein a width of the trench is less than or equal to 3.5 μm.

17. The electronic device of claim 11, wherein a depth of the trench is greater than or equal to 0.5 μm.

18. The electronic device of claim 11, wherein the intermediate layer comprises:
an emission layer disposed to correspond to the pixel electrode; and
a functional layer extending from the display area to the intermediate area,
wherein the functional layer is disposed on the separator.

19. The electronic device of claim 18, wherein the functional layer comprises:
a first portion disposed outside the groove; and
a second portion disposed inside the groove and separated from the first portion.

20. The electronic device of claim 11, wherein the opposite electrode comprises:
a first portion disposed outside the groove; and
a second portion disposed inside the groove and separated from the first portion.
